(19) United States
(12) Patent Application Publication
(10) Pub. No.: US 2014/0021801 A1
(43) Pub. Date: Jan. 23, 2014

(54) PROXIMITY SENSING STRUCTURE AND ELECTRONIC DEVICE HAVING PROXIMITY SENSING CAPABILITY

(71) Applicant: WISTRON CORPORATION, Taipei Hsien 221 (TW)

(72) Inventors: KUO-WEI KAO, TAIPEI HSIEN (TW); CHUNG-WEN CHEN, TAIPEI HSIEN (TW)

(73) Assignee: WISTRON CORPORATION, TAIPEI HSIEN (TW)

(21) Appl. No.: 13/690,013

(22) Filed: Nov. 30, 2012

(30) Foreign Application Priority Data
Jul. 19, 2012 (TW) 101125988

(51) Int. Cl. G01R 27/26; H01H 47/00

(52) U.S. Cl. CPC G01R 27/2605; H01H 47/00
USPC 307/125; 324/663

(57) ABSTRACT

The present invention relates to a proximity sensing structure, which is disposed in an article for detecting whether an object approaches the article. The article can be an electronic device. The proximity sensing structure comprises a first sensing electrode, a wire, a second sensing electrode, and a proximity sensor. Both ends of the wire are coupled electrically to the first and second sensing electrodes, respectively. The proximity sensor is coupled electrically to the wire, the first sensing electrode, and the second sensing electrode, and detects whether the object approaches the article according to an electrical status of the wire, the first sensing electrode, and the second sensing electrode. Thereby, the proximity sensing structure according to the present invention uses the wire to increase the sensing area. In addition, the wire design makes the disposal of the proximity sensing structure more flexible.

### FIELD OF THE INVENTION

The present invention relates generally to a proximity sensing structure and an electronic device having proximity sensing capability, and particularly to a proximity sensing structure and an electronic device having proximity sensing capability capable of increasing sensing area and improving disposal flexibility.

### BACKGROUND OF THE INVENTION

Current portable electronic products usually need to sense the approach of human bodies via proximity sensors for executing the corresponding events. For example, when a human body approaches, the processor of an electronic product will reduce the transmitting power of the antenna for complying with the regulations for electronic produces. The regulations include, for instance, the regulation of specific absorption rate (SAR), which regulates the absorption rate of electromagnetic waves for organisms has to be under a safety rate.

A proximity sensor is coupled to a sensing electrode for sensing its electrical status. When an object approaches the sensing electrode, the object will influence the electrical status of the sensing electrode. The proximity sensor senses the change in the electrical status of the sensing electrode, and thus knowing that the object approaches the sensing electrode. The electrical status of the sensing electrode is easily interfered by metals. Thereby, when disposing the sensing electrode, it has to consider if there is metal nearby. If so, there should be a proper clearance between the sensing electrode and the metal, which limits the locations of the sensing electrode and, in turn, limits the sensing area. Accordingly, there exist the problems of sensitivity and limited sensing area in the layout design of a general sensing electrode. When an object approaches an electronic product, owing to the limited sensing area, the proximity sensor may not sense the approach of the object to the electronic product. Consequently, the electronic product will not execute the corresponding event, and hence reducing the performance of the electronic product.

FIG. 1 shows a schematic diagram of the proximity sensing structure according to prior art. As shown in FIG. 1, the proximity sensing structure comprises a sensing electrode 10 and a proximity sensor 11. The sensing electrode 10 is disposed at the center of one side of a target 13 and coupled to the proximity sensor 11. The sensing electrode 10 has a sensing area 14. The target 13 shown in FIG. 1 can be an antenna of an electronic product. When an object 15 approaches the sensing electrode 10, the electrical status of the sensing electrode 10 will be influenced. Thereby, the proximity sensor 11 senses the change in the electrical status of the sensing electrode 10 and thus knowing that the object 15 approaches the sensing electrode 10. In other words, when the object 15 approaches the target 13 and gets into the sensing area 14, the proximity sensor 11 will detects the change in the electrical status of the sensing electrode 10. Thereby, the proximity sensor 11 senses that the object 15 approaches the target 13. Accordingly, the approach of the object 15 will enable the proximity sensor 11 to produce the corresponding signal. The electronic product then executes the corresponding event, such as lowering the transmitting power of the antenna, according to the signal produced by the proximity sensor 11.

Nonetheless, there are many metals 12 in general electronic products, for example, the metals used for heat dissipation or improving structural strength. Accordingly, the sensing electrode 10 is easily influenced by the metals 12. For avoiding completely the influence of the metals 12 on the sensing electrode 10, it is not possible to dispose the sensing electrode 10 at the center of one side of the target 13, lowering the flexibility in disposal and limiting the applicable electronic products.

In addition, FIG. 2 shows a schematic diagram of the proximity sensing structure according to another prior art. As shown in FIG. 2, the difference between the proximity sensing structures according to FIG. 1 and FIG. 2 is that the proximity sensing structure according to FIG. 2 adds a sensing electrode 16 and a proximity sensor 17. Besides, the sensing electrodes 10, 16 are disposed on both sides of the target 13; the sensing electrode 16 is coupled to the proximity sensor 17; and there is a sensing area 18. By sensing the electrical status of the sensing electrodes 10, 16, respectively, the proximity sensors 11, 17 of the proximity structure according to the latter prior art can sense whether the object 15 approaches the target 13. Nonetheless, the design of the proximity sensing structure will limit the sensing area, resulting in a sensing blind spot 19. In addition, the cost will be increased as well.

As shown in FIG. 2, because the sensing electrodes 10, 16 are disposed on both sides of the target 13, respectively, the sensing areas 14, 18 are located at both sides of the target 13. If the length of the target 13 is longer, for example, the target 13 is an antenna long term evolution (LTE), the sensing areas 14, 18 will not overlap, which means there will a sensing blind spot 19 between the sensing areas 14, 18 in which region the sensing electrodes 10, 16 cannot sense. When the object 15 approaches the target 13 and is located in the sensing blind spot 19, the object 15 will not influence the electrical status of the sensing electrodes 10, 16. Thereby, both of the proximity sensors 11, 17 will not sense the change in the electrical status of the sensing electrodes 10, 16. Consequently, the proximity sensors 11, 17 will not sense the object 15 approaching the target 13. No corresponding signal will be produced; no corresponding event will be executed. For example, the transmitting power of the antenna of an electronic product will not be lowered properly for complying with the SAR regulations. According to the above description, the sensing area of the proximity sensing structure according to the second prior art is severely limited and the sensitivity of proximity sensing is lowered. Moreover, two proximity sensors are required, which increases the cost.

Accordingly, the present invention uses a wire for improving the drawback of limited sensing area in the proximity sensing structure according to the prior art as well as increasing sensing sensitivity. In addition, the wire design according to the present invention makes the disposal location of the proximity sensing structure more flexible. The setup cost of the sensor is also reduced.

### SUMMARY

An objective of the present invention is to provide a proximity sensing structure, which uses a wire for increasing the sensing area of the proximity sensing structure and improving disposal flexibility. Besides, the cost can be further reduced.

For achieving the objective described above, the proximity sensing structure according to the present invention is disposed in an article, and comprises a first sensing electrode, a wire, a second sensing electrode, and a proximity sensor. An end of the wire is coupled electrically to the first sensing electrode. The second sensing electrode is coupled electrically to the other end of the wire. The proximity sensor is coupled electrically to the wire, the first sensing electrode, and the second sensing electrode, and detects whether an object approaches the article according to an electrical status of the wire, the first sensing electrode, and the second sensing electrode. Thereby, the proximity sensing structure according to the present invention uses the wire to extend the sensing area of the first sensing electrode and the sensing area of the second sensing electrode. Accordingly, the present invention can solve the sensing blind spot problem occurring in the sensing structure according to the prior art and improve the sensitivity. In addition, the wire design makes the disposal of the proximity sensing structure more flexible. Not requiring multiple proximity sensors, the cost can thus be reduced.

### BRIEF DESCRIPTION OF THE DRAWINGS

FIG. 1 shows a schematic diagram of the proximity sensing structure according to prior art;

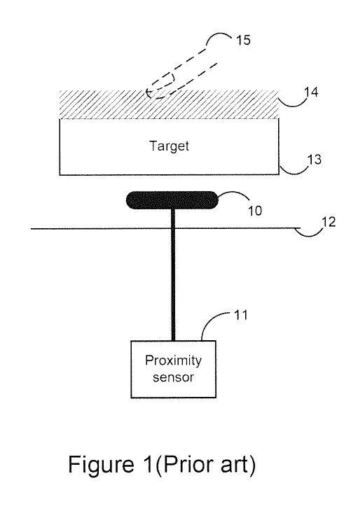

FIG. 2 shows a schematic diagram of the proximity sensing structure according to another prior art; and

FIG. 3 shows a schematic diagram of the proximity sensing structure according to an embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

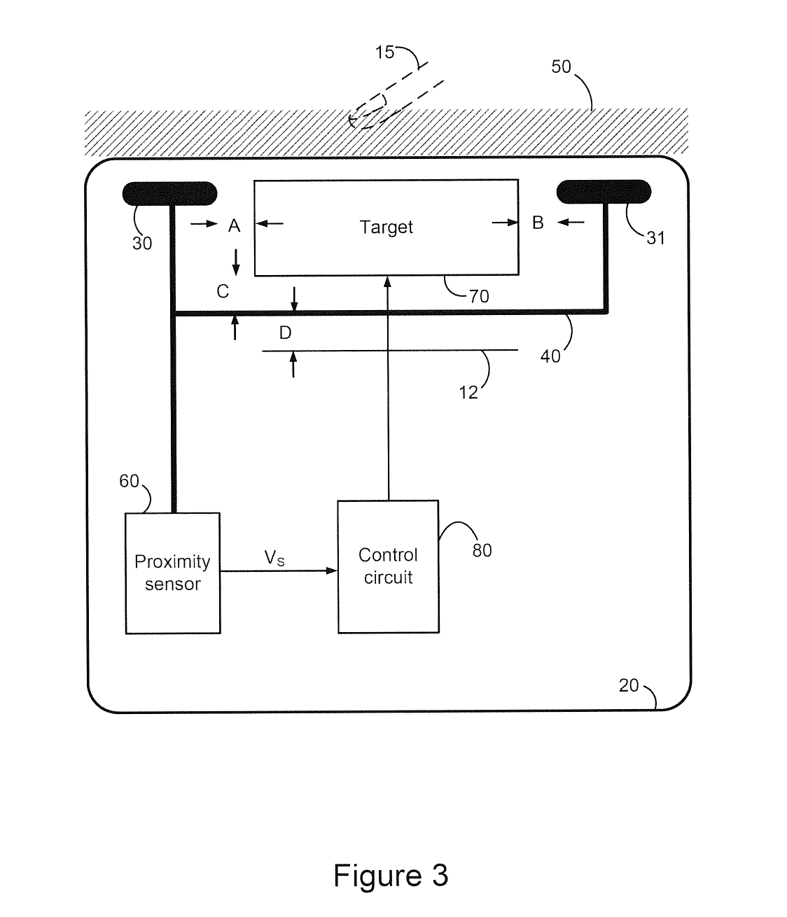

FIG. 3 shows a schematic diagram of the proximity sensing structure according to an embodiment of the present invention. A proximity sensing structure according to the present invention can be disposed in various types of electronic devices or non-electronic devices. An article 20 according to the present embodiment is an electronic device. Nonetheless, the applications of the proximity sensing structure according to the present invention are not limited to electronic devices only. As shown in the figure, the proximity sensing structure according to the present invention is disposed in the article 20 for detecting whether an object 15 approaches the article 20. As the object 15 approaches the article 20, the corresponding event is executed. For example, when the human body approaches the electronic device, the electronic device controls the antenna to lower the transmitting power for avoiding influences on human health. Alternatively, the article 20 is a smartphone. As the user answers the incoming calls, the proximity sensing structure can sense that the smartphone is close to the face. Thereby, the smartphone can further shut down the touch functions for preventing interruption of the calls caused by false touches of the user's face. Furthermore, the backlight can be shut down for saving power.

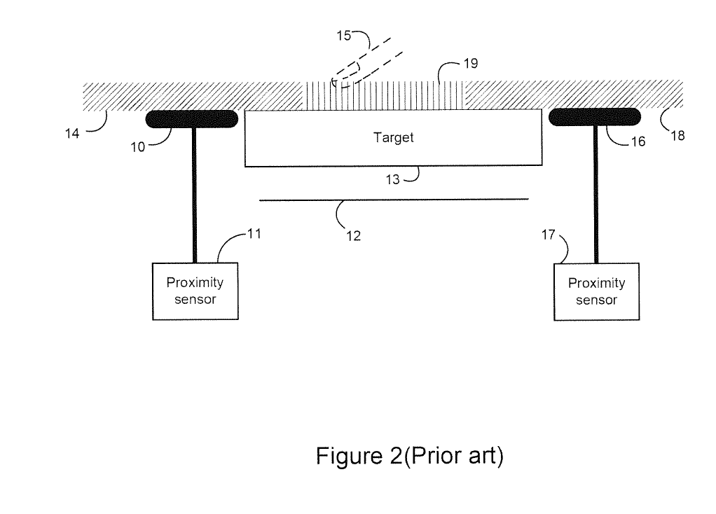

The proximity sensing structure according to the present invention comprises a first sensing electrode 30, a wire 40, and a second sensing electrode 31. The first sensing electrode 30 is coupled electrically to an end of the wire 40. The other end of the wire 40 is coupled electrically to the second sensing electrode 31. Thereby, the structure composed by the first sensing electrode 30, the wire 40, and the second sensing electrode 31 has a sensing area 50. In compared with the sensing areas 14, 18 shown in FIG. 2, the sensing area 50 obviously does not have the sensing blind spot 19. The proximity sensing structure further comprises a proximity sensor 60, which is coupled electrically to the first sensing electrode 30, the wire 40, and the second sensing electrode 31, and detects whether the object 15 approaches the article 20 according to an electrical status of the first sensing electrode 30, the wire 40, and the second sensing electrode 31. If the object 15 approaches the article 20 and so that enters the sensing area 50, the object 15 will influence the electrical status of the first sensing electrode 30, the wire 40, and the second sensing electrode 31. Hence, the proximity sensor 60 senses the changes in the electrical status and deduces that the object 15 approaches the article 20.

In addition, according to an embodiment of the present invention, the first sensing electrode 30, the wire 40, and the second sensing electrode 31 are respectively surrounding a specific target 70 such as an antenna. Thereby, the article 20 (the electronic device) can specially sense whether the object 15 approaches the target 70 for executing the corresponding event. As shown in the figure, the first sensing electrode 30 is located at a first side of the target 70 of the article 20; the second sensing electrode 31 is located at a second side of the target 70; and the wire 40 is located at a third side of the target 70. In other words, the first sensing electrode 30, the wire 40, and the second sensing electrode 31 are arranged in a U-shape. Hence, the sensing area 50 of the proximity structure according to the present invention can cover the length of the whole target 70 for sensing accurately whether the object 15 approaches the target 70. Nonetheless, the embodiment described above is only an embodiment of the present invention. The first sensing electrode 30, the wire 40, and the second sensing electrode 31 according to the present invention need not to be disposed surrounding the target 70.

The first and second sensing electrodes 30, 31 described above can be any electrical conductors such as copper foils, transparent conductive films, or indium tin oxide (ITO). In addition, the wire 40 can be a single-core wire or any metal wire. Relative to the proximity sensor 60, the first sensing electrode 30, the wire 40, and the second sensing electrode 31 are equivalent to external capacitors. As the object 15 approaches the first sensing electrode 30, the wire 40, and the second sensing electrode 31, the capacitance will be influenced. Namely, the electrical status of the first sensing electrode 30, the wire 40, and the second sensing electrode 31 will be changed. The proximity sensor 60 detects the change in electrical status for detecting of the object 15 approaches the article 20.

The proximity sensor 60 according to the present invention can be an integrated circuit (IC), which can be a currently available sensor such as the IC model number STM8T413. Because the types of the proximity sensor 60 are abundant with various sensing methods, which mainly sense the capacitance or voltage status, the details will not be described here.

The disposal locations of the first sensing electrode 30, the wire 40, and the second sensing electrode 31 also determine the sensing area 50. If the disposal locations of the first sensing electrode 30, the wire 40, and the second sensing electrode 31 are too close to a metal 12, the first sensing electrode 30, the wire 40, and the second sensing electrode 31 are vulnerable to the interference of the metal 12. Accordingly, the electrical status of the first sensing electrode 30, the wire 40, and the second sensing electrode 31 is influenced, which leads to shrinkage of the sensing area 50 and reduction in the sensitivity of the proximity sensing structure. Thereby, if the target 70 is a metal, there will be an interval between the first sensing electrode 30, the wire 40, the second sensing electrode 31, respectively, and the target 70 for avoiding interference by the target 70 as well as influencing the target 70. There is a first interval A between the first sensing electrode 30 and the target 70; there is a second interval B between the second sensing electrode 31 and the target 70; and there is a third interval C between the wire 40 and the target 70. A preferred distance of the first, second, and third intervals A, B, C is greater than 5 mm.

Moreover, the metal 12 is usually disposed in the article 20. The metal 12 can be a metallic plate or frame. Thereby, there should be a fourth interval D between the wire 40 and the metal 12. The proper distance of the fourth distance D is also greater than 5 mm. In addition, the disposal method for the first and second sensing electrodes 30, 31 is the same as the one for the wire 40. There should be intervals to any metal for avoiding interference by the metal.

Referring again to FIG. 3. Thanks to the wire 40 according to the present invention coupled between the first and second sensing electrodes 30, 31, the sensing area is being expanded. The sensing areas 14, 18 shown in FIG. 2 are being extended to the sensing area 50 shown in FIG. 3. The sensing blind spot 19 will no longer exist between the sensing areas 14, 18. Thereby, when the object 15 approaches the middle of the target 70, the proximity sensing structure according to the present invention still can detect that the object 15 is close to the target 70 of the article 20. The object 15 can be an organism, a finger, or other electrically conductive objects. Besides, the proximity sensing structure according to the present invention can be disposed in various articles 20, which can be various electronic devices. The target 70 can be an antenna, for example, the antenna of a smartphone or a tablet computer, for detecting whether a human body approaches the smartphone or the tablet computer and for controlling and lowering the transmitting power of the antenna for complying with the SAR safety regulation.

The article 20 further includes a control circuit 80 for executing an event according to a sensing signal Vₛ transmitted by the proximity sensor 60. The event can be disabling the internal circuit, lowering the transmitting power of the antenna, or activating the power-saving mechanism in the electronic product. According to an embodiment of the present invention, the event is to control the operation of the target 70, which is an antenna. In other words, the control circuit 80 controls the transmitting power of the antenna.

As shown in FIG. 3, when the object 15, for example, a human body, approaches the article 20, the electrical status of the first sensing electrode 30, the wire, and the second sensing electrode 31 will be influenced. The proximity sensor 60 will sense the change in electrical status and output a low-level sensing signal Vₛ. The control circuit 80 then can know that the object 15 approaches the antenna according to the low-level sensing signal Vₛ and control the antenna to lower the transmitting power of the antenna. On the contrary, if the object 15 does not approach the article 20, the proximity sensor 60 will not detect the change in electrical status. It will then output a high-level sensing signal Vₛ. The control circuit 80 controls the antenna to maintain the original transmitting power according to the high-level sensing signal Vₛ.

In addition, according to another embodiment of the present invention, when the object 15 approaches the electronic device 20, the proximity sensor 60 outputs the high-level sensing signal Vₛ. The control circuit 80 controls the transmitting power of the antenna according to the high-level sensing signal Vₛ. Thereby, the present invention does not limit the voltage level of the sensing signal Vₛ output by the proximity sensor 60 as the object 15 approaches the electronic device 20. Further, the present invention does not limit the voltage level of the sensing signal Vₛ, according to which voltage level the control circuit 80 executes the corresponding event.

Furthermore, the present invention can dispose the proximity sensing structure in other locations of the article 20 by using the wire 40. Alternatively, the proximity sensing structure can be disposed surrounding other devices inside the article 20. If the size of other targets is smaller and a smaller sensing are is required, the wire 40 can be shortened to shrink the sensing area for meeting the requirements in application. Besides, the proximity sensing structure can match up other changes in application. The details will not be described further. According to the description above, the proximity sensing structure according to the present invention can adjust the sensing area according to the requirement in application. And because the wire 40 is small and flexible, the disposal is flexible. Because only one proximity sensor 60 is required according to the present invention, the disposal cost is low.

To sum up, the present invention relates to a proximity sensing structure, which is disposed in an article for detecting whether an object approaches the article. The article can be an electronic device. The proximity sensing structure comprises a first sensing electrode, a wire, a second sensing electrode, and a proximity sensor. Both ends of the wire are coupled electrically to the first and second sensing electrodes, respectively. The proximity sensor is coupled electrically to the wire, the first sensing electrode, and the second sensing electrode, and detects whether the object approaches the article according to an electrical status of the wire, the first sensing electrode, and the second sensing electrode. Thereby, the proximity sensing structure according to the present invention uses the wire to solve the sensing blind spot problem occurring between two sensing electrodes according to the prior art. Accordingly, the sensing area and the sensitivity are improved. In addition, the wire design makes the disposal of the proximity sensing structure more flexible.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A proximity sensing structure, disposed in an article, used for detecting whether an object approaches said article, and comprising:
a first sensing electrode;
a wire, having an end coupled electrically to said first sensing electrode;
a second sensing electrode, coupled to the other end of said wire; and
a proximity sensor, coupled electrically to said wire, said first sensing electrode, and said second sensing electrode, and detecting whether said object approaches said article according to an electrical status of said wire, said first sensing electrode, and said second sensing electrode.

2. The proximity sensing structure of claim 1, wherein said first sensing electrode, said second sensing electrode, and said wire are located surrounding a target of said article.

3. The proximity sensing structure of claim 2, wherein said first sensing electrode is located at a first side of said target of said article, said second sensing electrode is located at a second side of said target of said article, and said wire is located at a third side of said target of said article.

4. The proximity sensing structure of claim 2, wherein there is an interval between said first sensing electrode, said second sensing electrode, said wire, respectively, and said target.

5. The proximity sensing structure of claim 4, wherein said interval is greater than 5 millimeters, respectively.

6. The proximity sensing structure of claim 2, wherein said first sensing electrode, said second sensing electrode, and said wire are disposed at the outer side of said target of said article, respectively, and arranged in U-shape.

7. The proximity sensing structure of claim 1, wherein said electrical status can be a voltage status or a capacitance status.

8. An electronic device having proximity sensing capability, comprising:
a first sensing electrode;
a wire, having an end coupled electrically to said first sensing electrode;
a second sensing electrode, coupled to the other end of said wire;
a proximity sensor, coupled electrically to said wire, said first sensing electrode, and said second sensing electrode, and outputting a sensing signal according to an electrical status of said wire, said first sensing electrode, and said second sensing electrode for detecting whether an object approaches said electronic device; and
a control circuit, coupled electrically to said proximity sensor, and executing an event according to said sensing signal.

9. The electronic device having proximity sensing capability of claim 8, wherein said first sensing electrode, said second sensing electrode, and said wire are located surrounding a target of said electronic device.

10. The electronic device having proximity sensing capability of claim 8, wherein said control circuit controls the transmitting power of an antenna of said electronic device according to said sensing signal.
